(19) United States
(12) Patent Application Publication
(10) Pub. No.: US 2006/0007999 A1
(43) Pub. Date: Jan. 12, 2006

(54) Method and system for enhancing image rejection in communications receivers using test tones and a baseband equalizer

(76) Inventors: Ramon A. Gomez, San Juan Capistrano, CA (US); Donald G. McMullin, Laguna Hills, CA (US)

Correspondence Address: MCANDREWS HELD & MALLOY, LTD, 500 WEST MADISON STREET, SUITE 3400, CHICAGO, IL, 60661, US

(21) Appl. No.: 11/029,733

(22) Filed: Jan. 5, 2005

Related U.S. Application Data
(60) Provisional application No. 60/586,328, filed on Jul. 8, 2004.

(51) Int. Cl. H03H 7/30

(52) U.S. Cl. 375/235

(57) ABSTRACT

Certain embodiments of the invention provide a method and system for enhancing image rejection in communications receivers. A test tone signal may be injected into a receiver. A quadrature error in an in-phase (I) channel and a quadrature (Q) channel of the receiver may be estimated based on the injecting of the test tone signal into the receiver. A plurality of equalizer coefficients may be adjusted to correct the estimated quadrature error in the I channel and the Q channel of the receiver. A corrected I channel and a corrected Q channel may be generated corresponding to the I channel and the Q channel in the receiver based on the adjusting of the equalizer coefficients.

### CROSS-REFERENCE TO RELATED APPLICATIONS/INCORPORATION BY REFERENCE

This application makes reference to, claims priority to, and claims the benefit of U.S. Provisional Patent Application Ser. No. 60/586328 (Attorney Docket No. 15901 US01), filed on Jul. 8, 2004.

The above stated application is incorporated herein by reference in its entirety.

### FIELD OF THE INVENTION

Certain embodiments of the invention relate to communications receivers. More specifically, certain embodiments of the invention relate to a method and system for enhancing image rejection in communications receivers using test tones and a baseband equalizer.

### BACKGROUND OF THE INVENTION

Conventional direct-conversion communications receivers generally rely on radio frequency (RF) or local oscillator (LO) signals that have been accurately split into quadrature components to produce in-phase (I) and quadrature (Q) baseband signals that may be used to reconstruct the message waveform. Similar principles are also utilized in low-IF receivers to achieve adequate image rejection. These types of receivers are increasingly popular because of their reduced reliance on RF or IF selectivity solely to achieve image rejection, leading to lower cost and size.

Based on design, some communication systems may require only a modest amount of image rejection, obtainable without trimming or calibrating the quadrature generation circuits. Other communication systems, for example, terrestrial broadcast systems or cable television, require very high levels of image rejection. In the case of terrestrial broadcast systems, there are often signals present in the image band of a receiver with much higher power levels than the desired carrier. This may result from close proximity to an interfering antenna, for example, and may be due to co-channel interference. In the case of analog cable television and other analog television broadcast systems, high levels of image rejection are required because the signal-to-interference (S/I) ratio must be very large for acceptable quality.

Achieving very high levels of image rejection or l-Q balance, for example, >40 dB for 1 GHz signals, roughly, may require some form of trimming or calibration. A plurality of methods suitable for implementation in integrated circuits (IC's) have been proposed. For example, U.S. Pat. No. 6,714,776 entitled “System and Method for An Image Rejection Single Conversion Tuner With Phase Error Correction” provides one such method suitable for implementing in an IC. This invention discloses a single conversion tuner, which generally utilizes phase shifted in-phase and quadrature signal paths as an image rejection circuit. The entire signal bandwidth is processed within the tuner by utilizing broadband input low noise amplifier (LNA) and mixer circuits. The invention adds a test tone to the RF signal and compares the phase of the down-converted I and Q test tones to obtain an error signal, which is utilized to control the quadrature balance of the LO's. The I and Q channels may not have the same amplitude and may not be at perfect quadrature with respect to each other. As a result of imperfect I-Q matching, the performance of the receiver may deteriorate.

Tuning may involve translating signals in frequency. If a desired channel is to be translated to an IF by mixing with a local oscillator that is lower in frequency, then a channel two times the IF frequency below the desired channel may be translated to negative IF. Negative intermediate frequencies interfere with the desired channel at the positive IF. This interfering channel may be referred to as an image channel and may be rejected to a large degree for proper reception. Image rejection may be addressed with filters and/or with image-reject mixers. In a single-conversion tuner, a notch filter may be used to reject the image channel prior to frequency translation. The performance of such a filter may be limited to 50 to 60 dB, for example, in the UHF component of the TV band (470 MHz and up). Better performance may be possible with dual-conversion tuners, where the first IF filter may be adapted to suppress the image channel by an arbitrary amount, depending on the cost of the filter. For cost-effective, dual-conversion tuning systems, the preferred approach may be to use a reasonably priced surface-acoustic wave (SAW) filter at first IF to achieve around 40 to 50 dB, for example, by itself, and then to complement it with a specialized mixer called an image-reject mixer. Such a mixer may be adapted to achieve an additional 35 to 40 dB, for example, of suppression. The combination allows for consistent image rejection in the range of better than 70 dB, for example.

Other methods may infer the quadrature balance from the I and Q baseband signals and generate an error signal accordingly. One such method is described in “A Single-Chip tuner for DVB-T” by Dawkins et al, IEEE Journal for Solid State Circuits Vol. 38 No.8, August 2003 (IEEE publication 0018-9200/03). Another such method is described in “Direct Conversion—How to Make it Work in TV Tuners” by Aschwanden, IEEE Transactions on Consumer Electronics, Vol. 42, No. 3, Aug. 1996 (IEEE Publication No. 0098,3063/96). It has been proposed to use this error signal to control an equalizer, which then maintains I and Q balance.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Certain embodiments of the invention provide a method for enhancing image rejection in communications receivers. A test tone signal may be injected into a receiver. A quadrature error in an in-phase (I) channel and a quadrature (Q) channel of the receiver may be estimated based on the injecting of the test tone signal into the receiver. A plurality of equalizer coefficients may be adjusted to correct the estimated quadrature error in the I channel and the Q channel of the receiver. A corrected I channel and a corrected Q channel may be generated, which corresponds to the I channel and the Q channel in the receiver based on the adjusting of the equalizer coefficients.

In an embodiment of the invention, the test tone signal may be generated by utilizing a direct digital frequency synthesizer. In this regard, the test tone signal generated by the direct digital frequency synthesizer may be converted into an analog signal injected at RF or a first IF frequency. The test tone signal may be injected at a first IF frequency having a narrow bandwidth to improve the quadrature accuracy of the second image reject mixer in a double conversion tuner. An amplitude error may be corrected in the I channel and the Q channel of the receiver. A phase error may be corrected in the I channel and the Q channel of the receiver. The I channel and the Q channel of the receiver may be filtered to allow the injected test tone signal. The injected test tone signal may have a high signal to noise ratio.

Another embodiment of the invention may provide a machine-readable storage, having stored thereon, a computer program having at least one code section executable by a machine, thereby causing the machine to perform the steps as described above in the method and system for enhancing image rejection in communications receivers using test tones and a baseband equalizer.

Another embodiment of the invention provides a system for enhancing image rejection in communications receivers. A test tone generator may be adapted to inject a test tone signal into a receiver. Circuitry may be adapted to estimate a quadrature error in an in-phase (I) channel and a quadrature (Q) channel of the receiver based on the injecting of the test tone signal into the receiver. Circuitry may be adapted to adjust a plurality of equalizer coefficients to correct the estimated quadrature error in the I channel and the Q channel of the receiver. The system may comprise circuitry that may be adapted to generate a corrected I channel and a corrected Q channel corresponding to the I channel and the Q channel in the receiver based on the adjusting of the equalizer coefficients.

A direct digital frequency synthesizer may be adapted to generate the test tone signal and a digital-to-analog converter may be adapted to convert the generated test tone signal from the direct digital frequency synthesizer into an analog signal. The test tone generator may be adapted to inject the test tone signal into the RF or first IF stages of the receiver. The test tone generator may be adapted to inject the test tone signal at a first IF frequency having a narrow bandwidth to improve the quadrature accuracy. Circuitry may be adapted to correct an amplitude error in the I channel and the Q channel of the receiver. Circuitry may also be adapted to correct a phase error in the I channel and the Q channel of the receiver. A low pass filter may be adapted to filter the I channel and the Q channel of the receiver to allow the injected test tone signal. The injected test tone signal may have a high signal to noise ratio.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of a conventional direct-conversion receiver that may be utilized in connection with an embodiment of the invention.

FIG. 2 is a block diagram of an exemplary baseband equalizer that may be utilized for quadrature correction, in accordance with an embodiment of the invention.

FIG. 3 is a block diagram of an exemplary direct conversion tuner with quadrature correction, in accordance with an embodiment of the invention.

FIG. 4 is a block diagram of an exemplary test tone synthesizer, in accordance with an embodiment of the invention.

FIG. 5a is a block diagram of a double conversion tuner with quadrature correction and a complex mixer having separate I and Q components, in accordance with an embodiment of the invention.

FIG. 5b is a block diagram of a double conversion tuner with quadrature correction, where the test tone signals are injected at the first IF frequency, in accordance with an embodiment of the invention.

FIG. 6 is a flowchart illustrating exemplary steps for enhancing image rejection in communications receivers, in accordance with an embodiment of the invention.

### DETAILED DESCRIPTION OF THE INVENTION

Certain embodiments of the invention may provide a method for enhancing image rejection in communications receivers. A test tone signal may be injected into a receiver. A quadrature error in an in-phase (I) channel and a quadrature (Q) channel of the receiver may be estimated based on the injecting of the test tone signal into the receiver. A plurality of equalizer coefficients may be adjusted to correct the estimated quadrature error in the I channel and the Q channel of the receiver. A corrected I channel and a corrected Q channel may be generated corresponding to the I channel and the Q channel in the receiver based on the adjusting of the equalizer coefficients.

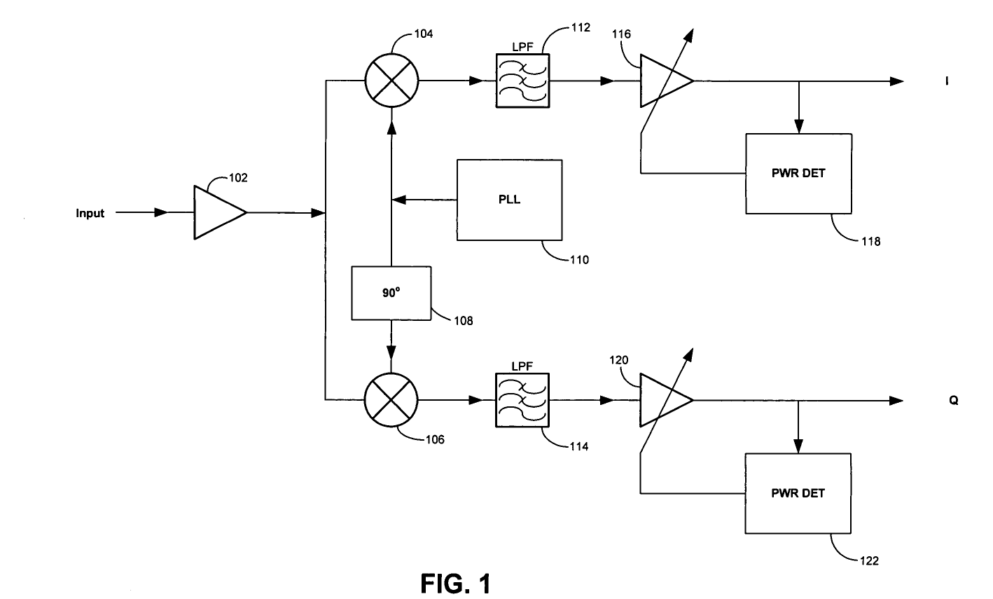

FIG. 1 is a block diagram of a conventional direct-conversion receiver that may be utilized in connection with an embodiment of the invention. Referring to FIG. 1, there is shown an amplifier 102, a plurality of mixers 104 and 106, a plurality of low pass filters 112 and 114, a plurality of linear gain amplifiers 116 and 120, a plurality of power detectors 118 and 122, a phase splitter 108 and a phase locked loop (PLL) 110.

The amplifier 102 may be adapted to receive an input signal and may generate an output signal that may be input to the plurality of mixers 104 and 106. The mixers 104 and 106 may be adapted to downconvert the analog RF substreams to baseband. The phase splitter 108 may be adapted to ensure that the mixer local oscillator inputs are in quadrature, indicating that they are 90 degrees out of phase with respect to each other. Alternatively, one path may be shifted by positive (+) 45 degrees and the other path may be shifted by negative (−) 45 degrees, for example. The phase locked loop 110 may be adapted to drive the mixer local oscillator inputs and the phase splitter 108. The plurality of low pass filters 112 and 114 may be adapted to filter the signals and may allow only a desired channel of frequencies. The plurality of linear gain amplifiers 116 and 120 may be adapted to maintain a constant amplitude and may be controlled by the plurality of power detectors 118 and 122.

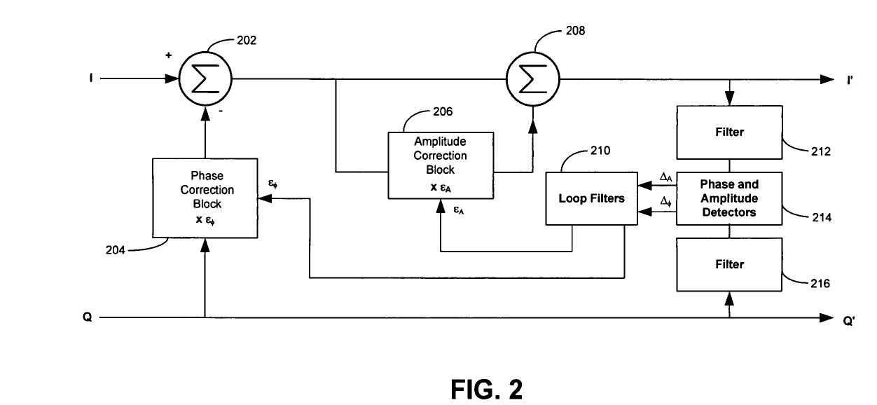

FIG. 2 is a block diagram of an exemplary baseband equalizer that may be utilized for quadrature correction, in accordance with an embodiment of the invention. Referring to FIG. 2, there is shown a plurality of summing nodes 202 and 208, a phase correction block 204, an amplitude correction block 206, a loop filter block 210, a plurality of filters 212 and 216 and a phase and amplitude detectors block 214.

The summing node 202 may be adapted to receive a plurality of inputs from the I channel and the phase correction block 204 and generate an output to the summing node 208. The phase correction block 204 may be adapted to receive a plurality of inputs from the Q channel and a phase coefficient signal ε_{φ} from the loop filter block 210. The amplitude correction block 206 may be adapted to receive a plurality of inputs from the I channel and an amplitude coefficient signal ε_{A} from the loop filter block 210. The summing node 208 may be adapted to receive a plurality of inputs from the I channel and a signal from the amplitude correction block 206 to generate a corrected amplitude and corrected phase I′ channel. The filters 212 and 216 may be adapted to filter and remove any out of band signals from the corrected I′ and Q′ channels and may generate outputs to the phase and amplitude detectors block 214.

The phase and amplitude detectors block 214 may be adapted to estimate a phase error and an amplitude error which may be denoted by Δ_{φ} and Δ_{A} respectively. The loop filter block 210 may be adapted to integrate the phase and amplitude errors received from the phase and amplitude detectors block 214 and generate coefficient signals ε_{φ} and ε_{A} that may provide the necessary correction in phase and amplitude in the I and Q channels. The loop filter block 210 may comprise a plurality of loop filters. The generated coefficient signals may also be adapted to improve the characteristics of feedback and loop bandwidth. The phase error signal may be adapted to control the amount of residual Q (I) signal subtracted from the I (Q) signal. The amplitude error signal may be adapted to control the amplitude of the I (Q) path signal.

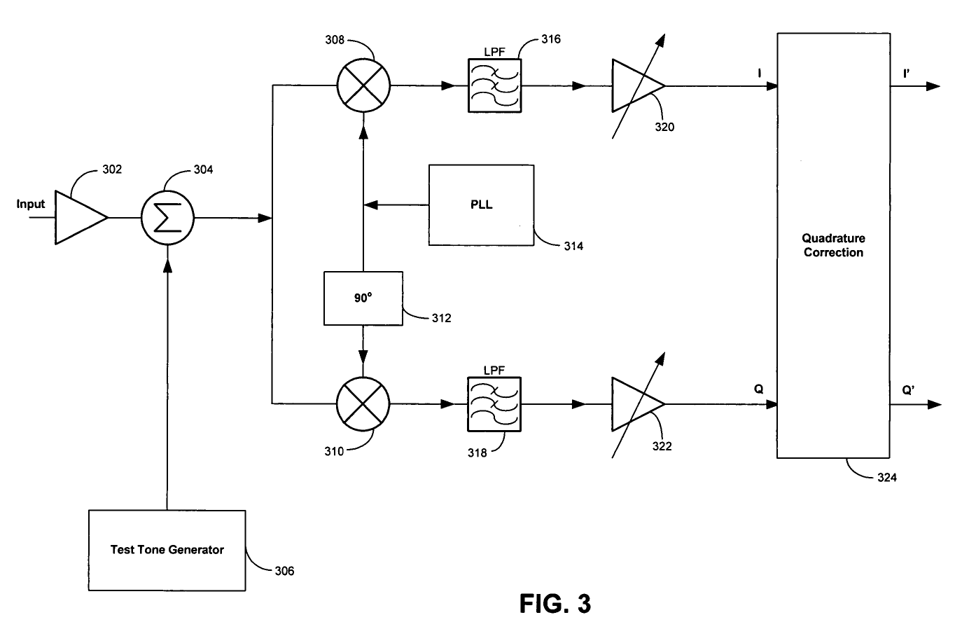

FIG. 3 is a block diagram of an exemplary direct conversion tuner with quadrature correction, in accordance with an embodiment of the invention. Referring to FIG. 3, there is shown an amplifier 302, a summer 304, a test tone generator 306, a plurality of mixers 308 and 310, a plurality of low pass filters 316 and 318, a plurality of linear gain amplifiers 320 and 322, a phase splitter 312, a phase locked loop PLL 314 and a quadrature correction block 324.

The amplifier 302 may be adapted to receive an input signal and may generate an output signal to the summer 304. The summer 304 may be adapted to receive a plurality of inputs from the amplifier 302 and the test tone generator 306 and generate an output signal that may be input to the plurality of mixers 308 and 310. The test tone generator 306 may comprise suitable logic and/or circuitry that may be adapted to generate an RF signal slightly different in frequency from the desired input signal that may be utilized to adjust the estimated quadrature error in the I channel and the Q channel of the receiver. The mixers 308 and 310 may be adapted to downconvert the analog RF substreams to baseband. The phase splitter 312 may be adapted to ensure that the mixer local oscillator inputs are 90 degrees out of phase with respect to each other. The phase locked loop 314 may be adapted to drive the mixer local oscillator inputs and the phase splitter 312. The plurality of low pass filters 316 and 318 may be adapted to filter the signals and may be adapted to allow only the test tone signals generated by the test tone generator 306. The plurality of linear gain amplifiers 320 and 322 may be adapted to maintain a constant amplitude and may be controlled by the quadrature correction block 324.

The quadrature correction block 324 may be adapted to receive the I and Q channel inputs that may comprise a combination of a desired signal and a test tone signal. The test tone signals are almost in quadrature with respect to the desired signal and have a high signal to noise ratio, which may increase the bandwidth and the convergence rate of the feedback loop. The I and Q channels may be digitized by analog-to-digital converters (ADCs) in the quadrature correction block 324. This has the advantage of permitting arbitrarily accurate measurement and correction of the quadrature errors, limited only by digital precision. The test tone signal may be injected between the quadrature mixers 308 and 310 and a front-end block, such as an amplifier 302, for example, which may provide significant reverse isolation preventing unwanted leakage of the test tone signal backwards into the communication medium.

Distinct from conventional systems such as that which is described in U.S. Pat. No. 6,714,776, both the phase and amplitude of the baseband I-Q signals may be corrected based on a comparison of the I and Q test tone signals. When compared to the systems described by, for example, Dawkins et al, and Aschwanden, which depend on features of the received signal to identify quadrature imbalance, the present invention is independent of the signal characteristics. In this regard, the present invention provides a method and system that may rapidly converge to the correct equalizer setting under all conditions, because the test tone signals may be strong enough to overcome received noise or interference.

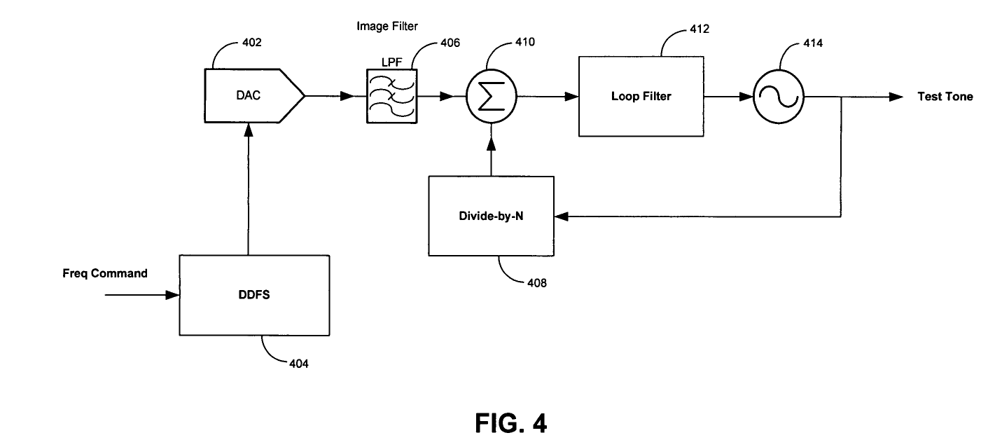

FIG. 4 is a block diagram of an exemplary test tone synthesizer, in accordance with an embodiment of the invention. Referring to FIG. 4, there is shown a digital-to-analog converter DAC 402, a direct digital frequency synthesizer 404, a low pass filter 406, a summer 410, a frequency divider 408, a loop filter 412 and a voltage controlled oscillator 414.

The direct digital frequency synthesizer 404 may comprise suitable logic and/or circuitry that may be adapted to generate a low frequency test tone signal in response to receiving an input frequency command signal. The test tone signal may be generated in an integrated circuit utilizing the direct digital frequency synthesizer 404 and optionally a PLL to frequency multiply and filter the output of the DDFS 404. This technique may produce a test tone signal with very fine frequency resolution, good spectral purity, and tunability over a wide range with a small amount of circuitry. The digital-to-analog converter 402 may be adapted to convert the digital test tone signal received from the direct digital frequency synthesizer 404 to an analog signal. The low pass filter 406 may be adapted to receive the analog signal from the DAC 402 and remove the DAC image to generate a smooth signal to the summer 410. The loop filter 412, the voltage controlled oscillator 414 and the frequency divider 408 may be a part of a traditional phase locked loop PLL. The frequency divider 408 may be adapted to divide an incoming frequency by a suitable number N. The summer 410 may be adapted to receive a plurality of inputs from the low pass filter 406 and the frequency divider 408 and generate an output to the loop filter 412. The voltage controlled oscillator 414 may be adapted to receive a signal from the loop filter 412 and generate an output test tone signal to the summer 304 [FIG. 3]. The phase locked loop may be adapted to multiply the frequency generated by the direct digital frequency synthesizer 404 up to a RF frequency, which may be the test tone output signal.

In operation, the direct digital frequency synthesizer 404 may be adapted to receive an input frequency command signal and generate a low frequency test tone signal to the digital-to-analog converter DAC 402. The digital-to-analog converter DAC 402 may be adapted to receive the low frequency digital test tone signal and convert it to an analog signal and transmit it to the low pass filter 406. The low pass filter 406 may be adapted to receive the analog signal from the DAC 402 and remove the DAC image to generate a smooth signal to the summer 410. The summer 410 may be adapted to receive a plurality of input signals from the low pass filter 406 and the frequency divider 408 and generate an output to the loop filter 412. The loop filter 412 may be adapted to receive an input signal from the summer 410 and generate an output signal to the voltage controlled oscillator 414. The voltage controlled oscillator 414 may be adapted to receive a signal from the loop filter 412 and generate an output test tone signal to the summer 304 [FIG. 3] and the frequency divider 408.

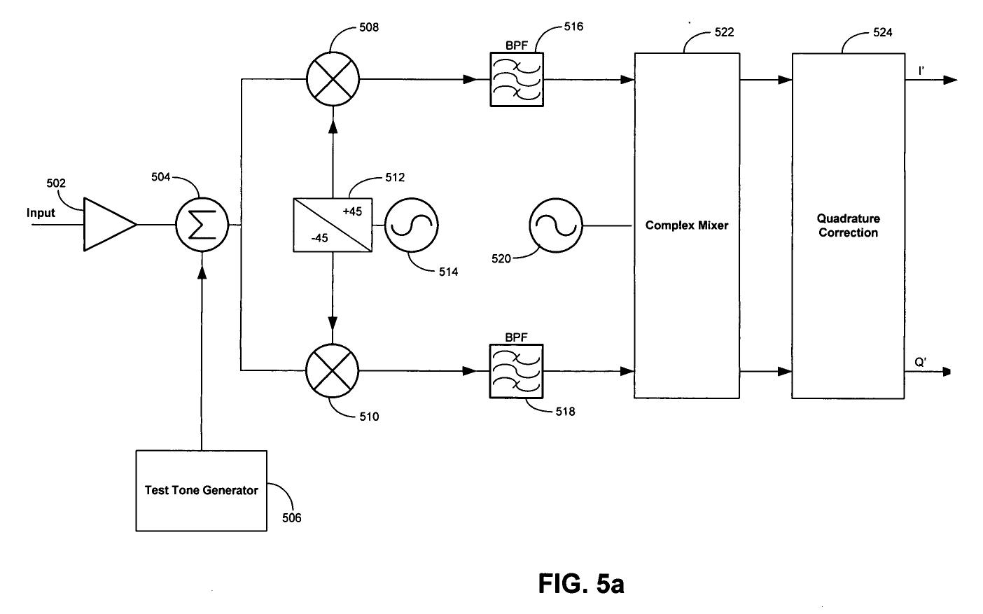

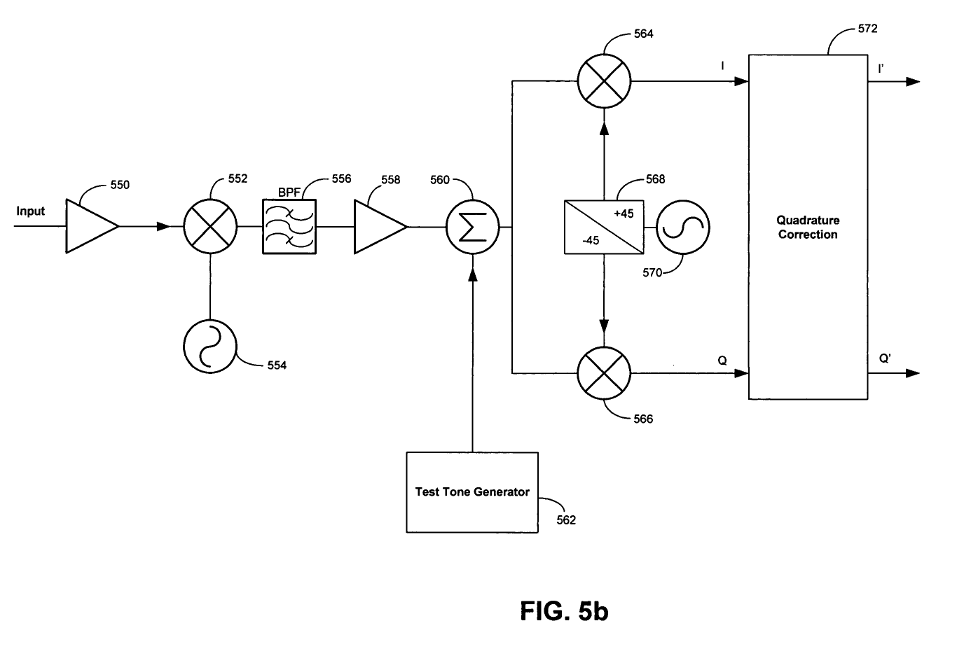

FIG. 5a is a block diagram of a double conversion tuner with quadrature correction and a complex mixer having separate I and Q components, in accordance with an embodiment of the invention. Referring to FIG. 5, there is shown an amplifier 502, a summer 504, a test tone generator 506, a plurality of mixers 508 and 510, a plurality of band pass filters 516 and 518, a plurality of voltage controlled oscillators 514 and 520, a complex mixer 522, a phase splitter 512 and a quadrature correction block 524.

The amplifier 502 may be adapted to receive an input signal and may generate an output signal to the summer 504. The summer 504 may be adapted to receive a plurality of inputs from the amplifier 502 and the test tone generator 506 and generate an output signal that may be input to the plurality of mixers 508 and 510. The test tone generator 506 may comprise suitable logic and/or circuitry that may be adapted to generate an RF signal slightly different in frequency from the desired input signal that may be utilized to adjust the estimated quadrature error in the I channel and the Q channel of the receiver. The mixers 508 and 510 may be adapted to downconvert the analog RF substreams to baseband. The phase splitter 512 may be adapted to ensure that the mixer local oscillator inputs are in quadrature, that is, they are 90 degrees out of phase with respect to each other.

The voltage controlled oscillator 514 may be adapted to drive the mixer local oscillator inputs and the phase splitter 512. The plurality of band pass filters 516 and 518 may be adapted to filter the signals and may be adapted to allow only the test tone signals generated by the test tone generator 506. The complex mixer 522 may be driven by the voltage controlled oscillator 520 and may receive the I and Q channel inputs from the band pass filters 516 and 518 respectively and generate a plurality of outputs to the quadrature correction block 524. The quadrature correction block 524 may be adapted to receive the I and Q channel inputs that may comprise a combination of a desired signal and a test tone signal. The test tone signals are almost in quadrature with respect to the desired signal and have a high signal to noise ratio, which may increase the bandwidth and the convergence rate of the feedback loop. The down converter mixers 508 and 510 may be adapted to downconvert the analog RF substreams to a first IF frequency. The complex mixer 522 may be adapted to downconvert the first IF frequency to a baseband frequency. The second mixer may be a part of a carrier tracking loop, which may be adapted to remove residual phase and frequency errors.

FIG. 5b is a block diagram of a double conversion tuner with quadrature correction, where the test tone signals are injected at the first IF frequency, in accordance with an embodiment of the invention. Referring to FIG. 5b, there is shown a plurality of amplifiers 550 and 558, a plurality of mixers 552, 564 and 566, a plurality of local oscillators 554 and 570, a band pass filter 556, a summer 560, a test tone generator 562, a phase splitter 568 and a quadrature correction block 572.

The amplifier 550 may be adapted to receive an input signal and may generate an output signal to the mixer 552. The voltage-controlled oscillator 554 may be adapted to drive the mixer 552. The mixer 552 may receive a plurality of inputs from the amplifier 550 and the voltage-controlled oscillator 554 and generate an output to the band pass filter 556. The band pass filter 556 may be adapted to receive an input signal from the mixer 552 and generate an output signal to the amplifier 558. The amplifier 558 may be adapted to receive an input signal from the band pass filter 556 and may generate an output signal to the summer 560. The summer 560 may be adapted to receive a plurality of inputs from the amplifier 558 and the test tone generator 562 and generate an output signal that may be input to the plurality of mixers 564 and 566. The test tone generator 562 may comprise suitable logic and/or circuitry that may be adapted to generate an RF signal slightly different in frequency from the desired input signal that may be utilized to adjust the estimated quadrature error in the I channel and the Q channel of the receiver. The mixers 564 and 566 may be adapted to downconvert the analog RF substreams to baseband and generate a plurality of output signals to the quadrature correction block 572. The phase splitter 568 may be adapted to ensure that the mixer local oscillator inputs are in quadrature, that is, they are 90 degrees out of phase with respect to each other.

The voltage-controlled oscillator 570 may be adapted to drive the mixer local oscillator inputs and the phase splitter 568. The quadrature correction block 572 may be adapted to receive the I and Q channel inputs that may comprise a combination of a desired signal and a test tone signal. The test tone signals are almost in quadrature with respect to the desired signal and have a high signal to noise ratio, which may increase the bandwidth and the convergence rate of the feedback loop. The down converter mixer 552 may be adapted to down convert the analog RF substream to a first IF frequency. The down converter mixers 564 and 566 may be adapted to upconvert the first IF frequency to a second IF frequency. By utilizing a double conversion architecture, the image channel interference may be significantly suppressed.

The test tone generator 562 may comprise suitable logic and/or circuitry that may be adapted to generate a test tone signal at the first IF frequency, which may be within a narrow frequency range. The first IF frequency may be 50 MHz, for example, while the input signal to the amplifier 550 may be a broadband signal in the frequency range of 50 MHz to 1 GHz, for example. As a result, the test tone generator 562, the plurality of mixers 564 and 566 may be adapted to operate at a narrower frequency range reducing hardware complexity and simplifying the generation of accurate quadrature balanced I and Q channels.

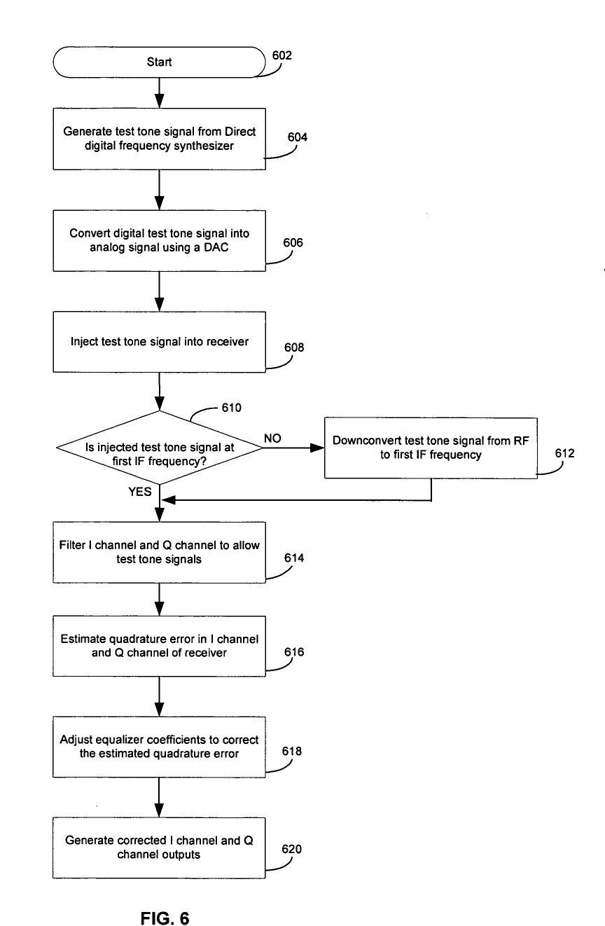

FIG. 6 is a flowchart illustrating exemplary steps for enhancing image rejection in communications receivers, in accordance with an embodiment of the invention. Referring to FIG. 6, there is shown, after start step 602, in step 604, a test tone signal may be generated by a direct digital frequency synthesizer. In step 606, the generated test tone signal from the direct digital frequency synthesizer may be converted into an analog signal by a digital-to-analog converter DAC. In step 608, the generated test tone signal may be injected into a receiver. In step 610, it may be checked if the injected test tone signal to the receiver is at first IF frequency. If the injected test tone signal is not at first frequency, in step 612, the test tone signal may be down converted to the first IF frequency from the RF substream and then in step 614, the I and Q channels may be filtered by low pass filters to allow only the test tone signals to pass through. If the injected test tone signals are injected at the first IF frequency, the mixers and the test tone generator may be adapted to operate at a narrower frequency range reducing hardware complexity and simplifying the generation of accurate quadrature balanced I and Q channels. In step 616, a quadrature error in the I channel and the Q channel of the receiver may be estimated based on the injecting of the test tone signal into the receiver. In step 618, a plurality of equalizer coefficients may be adjusted to correct the estimated quadrature error in the I channel and the Q channel of the receiver. In step 620, a corrected I channel and a corrected Q channel may be generated corresponding to the I channel and the Q channel in the receiver based on the adjusting of the equalizer coefficients.

Another embodiment of the invention provides a system for enhancing image rejection in communications receivers. A test tone generator 306 [FIG. 3] may be adapted to inject a test tone signal into a receiver. Circuitry may be adapted to estimate a quadrature error in an in-phase (I) channel and a quadrature (Q) channel of the receiver based on the injecting of the test tone signal into the receiver. Circuitry may be adapted to adjust a plurality of equalizer coefficients to correct the estimated quadrature error in the I channel and the Q channel of the receiver. The system may comprise circuitry that may be adapted to generate a corrected I channel and a corrected Q channel corresponding to the I channel and the Q channel in the receiver based on the adjusting of the equalizer coefficients.

A direct digital frequency synthesizer 404 [FIG. 4] may be adapted to generate the test tone signal and a digital-to-analog converter DAC 402 may be adapted to convert the generated test tone signal from the direct digital frequency synthesizer 404 into an analog signal. The test tone generator 306 [FIG. 3] may be adapted to inject the test tone signal into the I channel of the receiver and/or the Q channel of the receiver. For example, the test tone generator 306 may also be adapted to inject the test tone signal at any IF frequency. The test tone generator may be adapted to inject the test tone signal at a first IF frequency having a narrow bandwidth to improve the quadrature accuracy. Circuitry may be adapted to correct an amplitude error in the I channel and the Q channel of the receiver. Circuitry may also be adapted to correct a phase error in the I channel and the Q channel of the receiver. A low pass filter 316 [FIG. 3] and 318 may be adapted to filter the I channel and the Q channel of the receiver respectively, to allow the injected test tone signal. The injected test tone signal may have a high signal to noise ratio.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for enhancing image rejection in communications receivers, the method comprising:
injecting a test tone signal into a receiver;
estimating quadrature error in an in-phase (I) channel and a quadrature (Q) channel of said receiver based on said injecting of said test tone signal into said receiver;
adjusting equalizer coefficients to correct said estimated quadrature error in said I channel and said Q channel of said receiver; and
generating a corrected I channel and a corrected Q channel corresponding to said I channel and said Q channel in said receiver based on said adjusting of said equalizer coefficients.

2. The method according to claim 1, further comprising generating said test tone signal by a direct digital frequency synthesizer.

3. The method according to claim 2, further comprising converting said generated test tone signal from said direct digital frequency synthesizer into an analog signal.

4. The method according to claim 1, further comprising injecting said test tone signal at any IF frequency.

5. The method according to claim 1, further comprising injecting said test tone signal at a first IF frequency having a narrow bandwidth.

6. The method according to claim 1, further comprising correcting an amplitude error in said I channel and said Q channel of said receiver.

7. The method according to claim 1, further comprising correcting a phase error in said I channel and said Q channel of said receiver.

8. The method according to claim 1, further comprising filtering said I channel and said Q channel of said receiver to allow said injected test tone signal.

9. The method according to claim 1, wherein said injected test tone signal has a high signal to noise ratio.

10. A system for enhancing image rejection in communications receivers, the method comprising:
circuitry that injects a test tone signal into a receiver;
circuitry that estimates quadrature error in an in-phase (I) channel and a quadrature (Q) channel of said receiver based on said injecting of said test tone signal into said receiver;
circuitry that adjusts equalizer coefficients to correct said estimated quadrature error in said I channel and said Q channel of said receiver; and
circuitry that generates a corrected I channel and a corrected Q channel corresponding to said I channel and said Q channel in said receiver based on said adjusting of said equalizer coefficients.

11. The system according to claim 12, further comprising a direct digital frequency synthesizer that generates said test tone signal.

12. The system according to claim 13, further comprising a digital to analog converter that converts said generated test tone signal from said direct digital frequency synthesizer into an analog signal.

13. The system according to claim 10, further comprising a test tone generator that injects said test tone signal at any IF frequency.

14. The system according to claim 10, further comprising a test tone generator that injects said test tone signal at a first IF frequency having a narrow bandwidth.

15. The system according to claim 10, further comprising circuitry that corrects an amplitude error in said I channel and said Q channel of said receiver.

16. The system according to claim 10, further comprising circuitry that corrects a phase error in said I channel and said Q channel of said receiver.

17. The system according to claim 10, further comprising a low pass filter that filters said I channel and said Q channel of said receiver to allow said injected test tone signal.

18. The system according to claim 10, wherein said injected test tone signal has a high signal to noise ratio.

19. A communications receiver circuit, comprising:
a test tone generator block;
a summer coupled to an output of said test tone generator block and an output of an amplifier;
an in-phase (I) path coupled to an output of said summer;
a quadrature (Q) path coupled to said output of said summer;
a quadrature correction block coupled to an output of said I path;
a quadrature correction block coupled to an output of said Q path;
a phase splitter coupled to said I path and said Q path; and
a phase locked loop coupled to said I path and said Q path.

20. The communications receiver circuit according to claim 19, wherein said test tone generator block further comprises a direct digital frequency synthesizer that receives an input frequency command signal.

21. The communications receiver circuit according to claim 20, wherein said test tone generator block further comprises a digital-to-analog converter coupled to output of said direct digital frequency synthesizer.

22. The communications receiver circuit according to claim 21, wherein said test tone generator block further comprises a low pass filter coupled to an output of said digital-to-analog converter.

23. The communications receiver circuit according to claim 22, wherein said test tone generator block further comprises a summer coupled to an output of said low pass filter and input of a frequency divider.

24. The communications receiver circuit according to claim 23, wherein said test tone generator block further comprises a loop filter block coupled to an output of said summer.

25. The communications receiver circuit according to claim 24, wherein said test tone generator block further comprises a local oscillator coupled to an output of said loop filter block.

26. The communications receiver circuit according to claim 25, wherein said test tone generator block further comprises said frequency divider coupled to an output of said local oscillator.

27. The communications receiver circuit according to claim 19, wherein said I path further comprises a first mixer coupled to said output of said summer, output of said phase splitter and output of said phase locked loop.

28. The communications receiver circuit according to claim 27, wherein said I path further comprises a first low pass filter coupled to an output of said first mixer.

29. The communications receiver circuit according to claim 28, wherein said I path further comprises a first linear gain amplifier coupled to an output of said first low pass filter.

30. The communications receiver circuit according to claim 29, wherein said quadrature correction block is coupled to an output of said first linear gain amplifier.

31. The communications receiver circuit according to claim 19, wherein said Q path further comprises a second mixer coupled to said output of said summer, output of said phase splitter and output of said phase locked loop.

32. The communications receiver circuit according to claim 31, wherein said Q path further comprises a second low pass filter coupled to an output of said second mixer.

33. The communications receiver circuit according to claim 32, wherein said Q path further comprises a second linear gain amplifier coupled to an output of said second low pass filter.

34. The communications receiver circuit according to claim 33, wherein said quadrature correction block is coupled to an output of said second linear gain amplifier.

35. The communications receiver circuit according to claim 19, further comprising a first bandpass filter.

36. The communications receiver circuit according to claim 35, further comprising a complex mixer block coupled to an output of said first bandpass filter.

37. The communications receiver circuit according to claim 36, further comprising a local oscillator coupled to said complex mixer block.

38. The communications receiver circuit according to claim 36, further comprising said quadrature correction block coupled to an output of said complex mixer block.

39. The communications receiver circuit according to claim 19, further comprising a second bandpass filter.

40. The communications receiver circuit according to claim 39, further comprising a complex mixer block coupled to an output of said second bandpass filter.

41. The communications receiver circuit according to claim 19, further comprising a local oscillator coupled to said phase splitter.

42. The communications receiver circuit according to claim 19, further comprising a bandpass filter coupled to an input of said amplifier.

43. The communications receiver circuit according to claim 42, further comprising a mixer coupled to an input of said bandpass filter.

44. The communications receiver circuit according to claim 43, further comprising a local oscillator coupled to said mixer.

45. The communications receiver circuit according to claim 43, further comprising an amplifier coupled to an input of said mixer.
